(19) United States
(12) Patent Application Publication
(10) Pub. No.: US 2026/0344061 A1
(43) Pub. Date: Oct. 29, 2026

(54) PHOTOVOLTAIC COMPONENT LAMINATING DEVICE, PHOTOVOLTAIC COMPONENT LAMINATING MACHINE

(71) Applicant: Wuxi Zhichuangsheng Automation Equipment Co., Ltd., Wuxi (CN)

(72) Inventors: You Li, Shenzhen (CN); Yu Jin, Hejian (CN); Yifei Jia, Shenzhou (CN)

(21) Appl. No.: 19/664,303

(22) Filed: Apr. 30, 2026

(30) Foreign Application Priority Data
Dec. 24, 2025 (CN) 202511963951.3

(51) Int. Cl. H10F 19/80

(52) U.S. Cl. CPC H10F 19/80

(57) ABSTRACT

Provided are a photovoltaic component laminating device and a photovoltaic component laminating machine. The photovoltaic component laminating device includes at least one rigid laminated board, a lifting device, and a rigid sealing plate. The sealing plate has a first accommodation chamber below which the laminated board is accommodated, and the laminated board is provided inside the first accommodation chamber. The lifting device includes a lifting drive device and a fixing shaft. The sealing plate is provided above the laminated board, and the lifting drive device is provided above the sealing plate. The photovoltaic component laminating device and photovoltaic component laminating machine are conducive to maintaining the flatness of the laminated board, it can prevent the uneven laminating pressure caused by excessive downward bending of the edge of the laminated board, which leads to thin edges of the photovoltaic component and the occurrence of unqualified photovoltaic components.

### CROSS-REFERENCE TO RELATED APPLICATIONS

This application claims priority to Chinese Patent Application No. 202511963951.3, filed on Dec. 24, 2025, which is hereby incorporated by reference in its entirety.

### TECHNICAL FIELD

The present disclosure relates to the field of photovoltaic component lamination technologies, and in particular, to a photovoltaic component laminating device and a photovoltaic component laminating machine.

### BACKGROUND

Photovoltaic component laminating machines are important equipment for producing photovoltaic components. According to the different pressure components, it is divided into rigid plate photovoltaic component laminating machine and flexible rubber plate photovoltaic component laminating machine. The pressure applying component of the rigid plate photovoltaic component laminating machine is a rigid plate. The rigid laminated board is a part of the upper box, and its lower end is equipped with an inflatable sealing ring located above the heating plate of the lower box. When laminating, the upper box falls, and the inflatable sealing ring, rigid laminated board, and heating plate located below the rigid laminated board form a laminating chamber. Vacuum is drawn and heated inside the laminating chamber, and the photovoltaic component is pressed by the rigid laminated board and the heating plate. During this process, the middle part of the rigid laminated board arches upwards and the edges bend downwards, the edges are caused to bend downwards and the middle part to arch upwards. The pressure of the rigid laminated board on the edges of the photovoltaic component is greater than that in the middle part, resulting in thin edges of the photovoltaic component. The rubber plate laminating machine uses a silicone plate as the pressure applying component, and the upper part of the upper box is sealed by the silicone plate into a sealing chamber as the upper sealing chamber. After the upper and lower boxes are closed, the upper and lower boxes below the silicone plate form a sealing chamber as the lower sealing chamber. When applying pressure to the photovoltaic component, the upper sealing chamber is inflated, and the silicone plate is inflated into a bag shape due to its elasticity, which applies pressure to the photovoltaic component. This pressure applying method, because the silicone plate is in a bag shape, the pressure on the edge of the photovoltaic component is less than the pressure on the middle of the photovoltaic component, resulting in less pressure on the edge of the photovoltaic component and easy cracking. The above-mentioned objective technical problems have led to the production of defective photovoltaic components.

### SUMMARY

The present disclosure aims to provide a photovoltaic component laminating device and a photovoltaic component laminating machine to address the shortcomings of uneven pressure on photovoltaic components in existing technology.

The main objective of the present disclosure is achieved through the following technical solutions.

A photovoltaic component laminating device, including:
at least one rigid laminated board,
a lifting device, and
a rigid sealing plate,
a first accommodation chamber configured to accommodate the laminated board is provided below the sealing plate, the laminated board is provided in the first accommodation chamber,
the lifting device includes a lifting drive device and a fixing shaft, the sealing plate is provided above the laminated board, the lifting drive device is provided above the sealing plate, and a first through hole is provided on the sealing plate; a lower end of the fixing shaft is fixedly connected to the laminated board, and an upper end passes through the first through hole and is fixedly connected to an output end of the lifting drive device; the sealing plate is freely provided above the laminated board; when the lifting drive device drives the laminated board to rise, the sealing plate is driven to rise by the laminated board;
when the lifting drive device drives the laminated board to descend, the sealing plate descends synchronously with the laminated board by its own weight, when there are two or more laminated boards, and the two or more the laminated boards are horizontally arranged in parallel, and each of laminated boards is provided with at least one lifting device; a flexible cushion layer is fixedly provided on a surface of laminated boards that is opposite the photovoltaic component.

In some embodiments of the present disclosure, the sealing plate is hung on a protruding of the fixing shaft through an opening of the through hole, so that the sealing plate is configured to contact and connect with the laminated board and maintain a free state, and a lower surface of the laminated board faces the heating device.

In some embodiments of the present disclosure, a sealing device is provided on a lower end surface of the sealing plate, and the sealing device is an inflatable sealing ring; the inflatable sealing ring is communicated to an inflation device and an exhaust device respectively, a height of the first accommodation chamber is adjusted by adjusting an inflation amount of the inflatable sealing ring; a backing plate is provided on a lower end surface of the sealing plate on an inner side or an outer side of the sealing device, and the backing plate is configured to support the sealing plate.

In some embodiments of the present disclosure, the lifting drive device is a linear reciprocating driving device configured to control a lifting displacement of the laminated board, and the linear reciprocating driving device is a cylinder, an electric cylinder, or a servo motor.

In some embodiments of the present disclosure, a photovoltaic component laminating machine is provided, which includes an upper box and a heating plate, and the photovoltaic component laminating device above is used, where a second accommodation chamber configured to accommodate the sealing plate and the laminated plate is provided below an upper box body, the sealing plate is provided in the second accommodation chamber, the upper box is provided above the heating plate, and the two are configured to approach and move away from each other; when they approach to each other, they form a second sealing chamber, and when they move away from each other, a lid is opened and space is left, at least one sealing plate is provided in the second accommodation chamber; when the lifting device drives the laminated board to move down to its position, a first sealing chamber is formed between the sealing plate and the heating plate; after the lifting device moves up, the sealing plate and the laminated board move away from the heating plate, and the first sealing chamber is communicated to an inflation device and a vacuum extraction device respectively, the second sealing chamber is communicated to the inflation device and the vacuum extraction device respectively.

In some embodiments of the present disclosure, when laminating, the upper box body and sealing plate are first combined with the heating plate to form the first sealing chamber and the second sealing chamber, respectively, and then pressure is applied to the photovoltaic component; applying pressure to the photovoltaic component, inflating the second sealing chamber as an applied pressure and the lifting drive device does not apply pressure, or inflating the second sealing chamber as a main applied pressure and the lifting drive device applies an auxiliary pressure; where the auxiliary pressure of the lifting drive device is applied in an area where the pressure needs to be increased.

In some embodiments of the present disclosure, when the sealing plate and the laminated board are descended into place, the laminated board does not apply pressure to the photovoltaic component, and when the second sealing chamber is inflated, the laminated board begins to apply pressure to the photovoltaic component.

In some embodiments of the present disclosure, the lifting drive device is provided outside the upper box body, and a second through hole is provided on the upper box body; an upper end of the fixing shaft passes through the second through hole, and the lifting drive device is fixedly connected to the upper end of the fixing shaft through a lifting board; a corrugated pipe is provided between the lifting board and the upper box body, and an upper end of the corrugated pipe is connected to the lifting board in a sealing manner, and a lower end is connected to the upper box body in a sealing manner; the fixing shaft is provided inside the corrugated pipe and passes through the second through hole in a sealing manner through the corrugated pipe.

In some embodiments of the present disclosure, there are two corrugated pipes, namely an upper corrugated pipe and a lower corrugated pipe; an upper end of the upper corrugated pipe is fixedly connected to the lifting board for sealing, and a lower end thereof is fixedly connected to the upper box body for sealing; an upper end of the lower corrugated pipe is fixedly connected to the upper box body in a sealing manner, and a lower end thereof is fixedly connected to the sealing plate in a sealing manner; the fixing shaft is provided in the upper corrugated pipe and the lower corrugated pipe.

In some embodiments of the present disclosure, a fixing seat is fixedly provided on the upper box body, and a third through hole is provided on the fixing seat, the third through hole is arranged opposite to the second through hole; a first installation seat and a second installation seat are provided in a large-diameter hole of the third through hole; side walls of the first installation seat and the second installation seat are fixedly connected to a through hole wall of the fixing seat, and both the first installation seat and second installation seat are provided with through holes for the fixing shaft to pass through; an upper surface of the first installation seat is fixedly connected to a lower surface of the fixing seat in a sealing manner, and a lower surface of the first installation seat is fixedly connected to the upper surface of the second installation seat in a sealing manner; an upper end of the lower corrugated pipe is fixedly connected to the second installation seat in a sealing manner and is provided with an adapter shaft, the adapter shaft is in a shape of “T”, a top of the adapter shaft that is in “—” character shape is fixedly connected to the lifting board, and a lower end thereof is fixedly connected to the fixing shaft; a connection position between the fixing shaft and the adapter shaft is provided in the through hole of the fixing seat; the fixing shaft and the adapter shaft are fixedly connected and coaxially arranged.

The photovoltaic component laminating device using the structure of the present disclosure, when the laminated board is deformed by heat, due to the contact connection between its upper part and the sealing plate, and the free placement of the sealing plate above the laminated board, there will be no local stress concentration when heated. Therefore, the deformation amount is small and uniform, which will prevent the deformation of the laminated board and reduce the deformation amount of the laminated board. This is conducive to maintaining the flatness of the laminated board and can prevent the occurrence of unqualified photovoltaic components caused by uneven laminating pressure due to excessive downward bending of the edges of the laminated board, resulting in thin edges of the photovoltaic component.

The photovoltaic component laminating machine adopting the structure of the present disclosure forms the first sealing chamber by the sealing plate and the heating plate, and the second sealing chamber that is formed by the upper box body and the heating plate. The first sealing chamber is located inside the second sealing chamber, and inflate the second sealing chamber wit. The laminated board can obtain pressure to apply pressure to the photovoltaic component through the sealing plate, and the pressure directly acts on the sealing plate. The pressure obtained by the laminated board is the contact pressure, which is applied to the laminated board through the sealing plate, and then the laminated board applies pressure to the photovoltaic component. On the basis of reducing the deformation of the laminated board due to heat, the deformation of the laminated board can be further reduced, and the laminating quality can be improved.

### BRIEF DESCRIPTION OF DRAWINGS

FIG. 1 is a schematic diagram of a thermal deformation state of a laminated board of the existing photovoltaic component laminating machine.

FIG. 2 is a schematic front view of a structure of an embodiment of the photovoltaic component laminating machine of the present disclosure.

FIG. 3 is a partially enlarged schematic diagram of A in FIG. 1 of the present disclosure.

FIG. 4 is a schematic front view of a structure of a laminated assembly of the photovoltaic component according to an embodiment of the present disclosure.

Numeral reference: 1- first sealing chamber; 2- second sealing chamber; 3-upper box; 201- heating plate; 202- photovoltaic component; 300- laminating device; 301- backing plate; 302- inflatable sealing ring; 303- flexible cushion layer; 304- laminated board; 305- sealing plate; 306- first sealing device; 307- sealing plate body; 308- frame; 400- lifting device; 401- upper corrugated pipe; 402- lifting drive device; 403- lifting board; 404- adapter shaft; 405- lower corrugated pipe; 406- fixing seat; 407- second sealing device; 408- first installation seat; 409- second installation seat; 410- fixing shaft; 411- protruding; 412- hole; 413- second through hole.

### DESCRIPTION OF EMBODIMENTS

The preferred embodiments of the present disclosure will be described in detail with reference to the accompanying drawings, which constitute a part of the present disclosure and are used together with the embodiments to illustrate the principles of the present disclosure, and are not intended to limit the scope of the present disclosure.

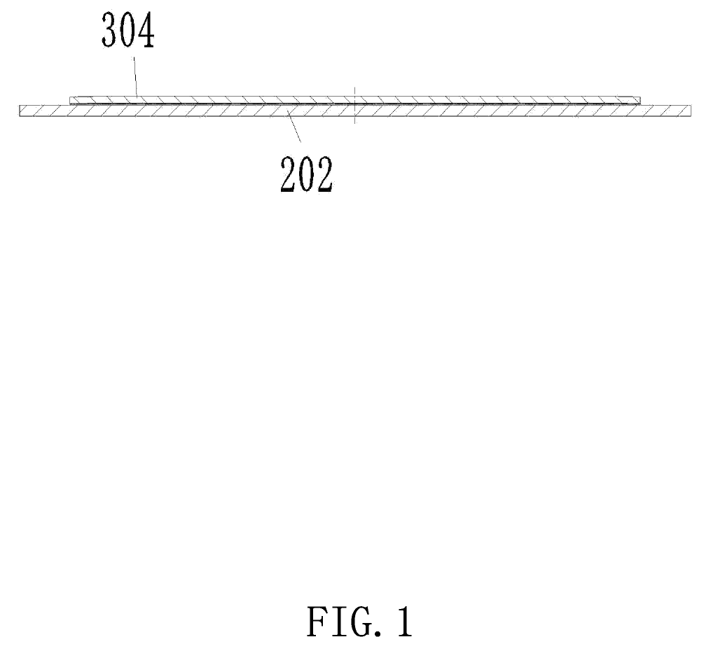

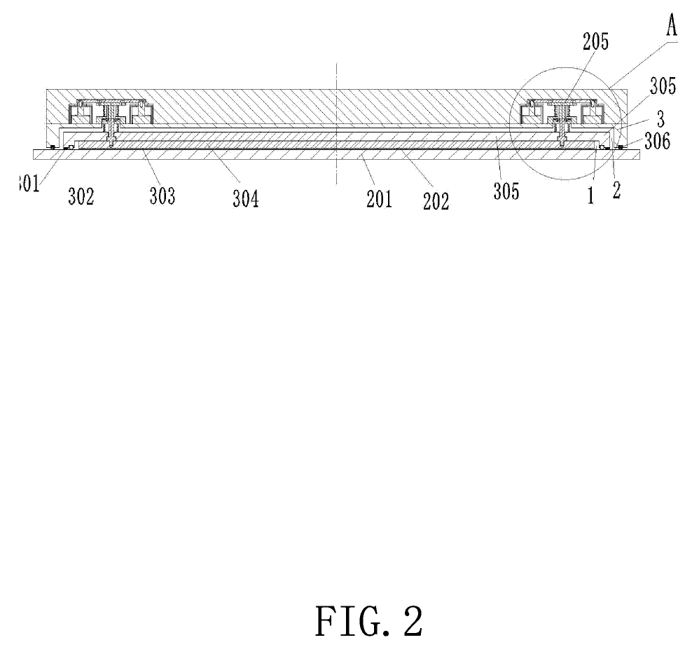

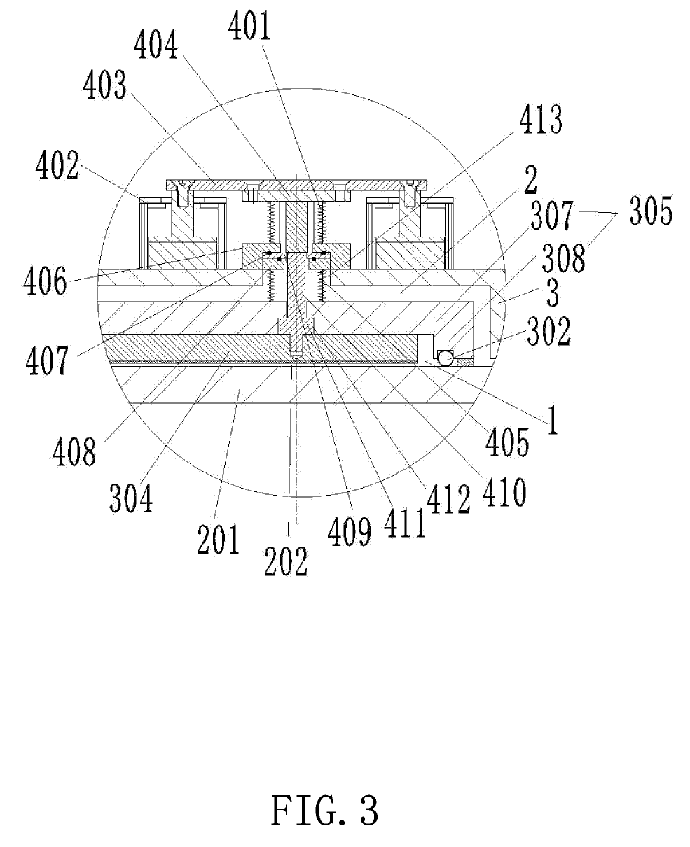

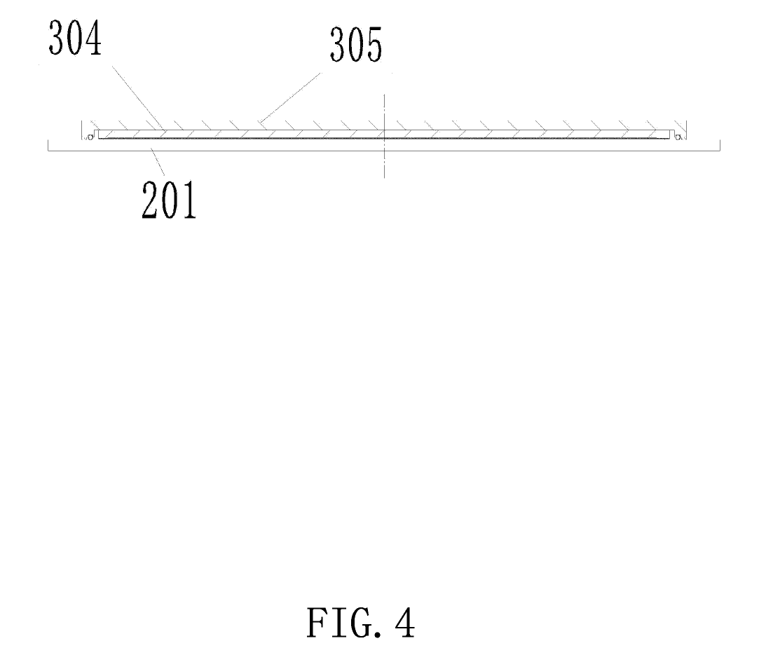

As shown in FIGS. 1-4, a laminating machine of an embodiment of the present disclosure includes an upper box 3 and a lower box. The lower box includes a heating plate 201, and the upper box 3 is driven up and down by a reciprocating lifting device 400 of the upper box 3 to open and close a lid with the lower box. When the lid is opened, the upper box 3 leaves the heating plate 201, and when the lid is closed, the upper box 3 and the heating plate 201 are sealed by a first sealing device 306 to form a second sealing chamber 2. The first sealing device 306 can be a silicone strip or other high-temperature resistant sealing ring that can achieve sealing. It also includes a laminating device 300 and a lifting device 400. The laminating device is used to work together with the heating plate 201 to apply pressure to the photovoltaic component 202 and provide space for lamination. The lifting device 400 is used to lift the laminated board 304 of the laminating device, and the laminated board 304 is caused to rise and fall, thereby applying pressure or leaving the photovoltaic component 202. When the lifting device 400 drives the laminated board 304 to rise, the laminated board 304 leaves the photovoltaic component 202, and when the laminated board 304 is driven to fall, it applies pressure to the photovoltaic component 202. The laminating device is located in the space formed below the upper box 3. When the upper box 3 and the lower box are closed, the laminating device is located in the second sealing chamber 2 formed by the two. The second sealing chamber 2 is communicated to an inflation device and a deflation device respectively. The inflation and deflation device can inflate the second sealing chamber 2, and the deflation device releases the gas inside the second sealing chamber 2.

In the present disclosure, the laminating device 300 includes the laminated board 304 and a sealing plate 305. The laminated board 304 is a rigid plate located above the heating plate 201 and acts together with the heating plate 201as a laminating component on the photovoltaic component 202, applying pressure to the photovoltaic component 202 located above the heating plate 201. The heating plate 201 mainly supports the photovoltaic component and heats the photovoltaic component 202. The sealing plate 305 is located between the upper box 3 and the laminated board 304, which plays a protective role in the deformation of the laminated board 304 and is combined with the heating plate 201 to form a first sealing chamber 1. The sealing plate 305 is also a rigid component, including a plate-shaped sealing plate body 307 and a frame 308. The frame 308 is located around a surface of the sealing plate 305 facing the laminated board 304, and the frame308 and the sealing plate body 307 form the first accommodation chamber that accommodates the laminated board 304 and the photovoltaic component 202. When the sealing plate 305 connects the heating plate 201 under the action of lifting component, it forms the first sealing chamber 1 through an inflatable sealing ring 302, and the laminated board 304 is located inside the first sealing chamber 1. The connection between the frame 308 and the sealing plate body 307 can be detachable and fixed, or integrated.

The lifting device 400 includes a fixing shaft 410 and a lifting drive device 402. A lower end of the fixing shaft 410 is fixedly connected to the laminated board 304, usually through threaded connection or welding connection. An upper end passes through a first through hole provided on the sealing plate 305 and is connected to an output end of the lifting drive device 402 above the sealing plate 305. The lifting drive device 402 is fixed by the upper box 3. Using the above structure, the sealing plate 305 is supported by the laminated board 304 and freely located above the laminated board 304. The sealing plate 305 itself has no fixed points, so when subjected to heat from the outside, the deformation is small or uniform, which can maintain the flatness of the sealing plate body 307. At the same time, because the laminated board 304 is in contact with it, when the laminated board 304 deforms due to heat, the sealing plate 305 can prevent it from deforming and reduce the deformation of the laminated board 304. Specifically, when heated, the laminated board 304 deforms and arches upwards in the middle. However, because the sealing plate 305 is not fixedly connected to any device and is in a free state without fixed points, and because the thickness of the laminated board 304 itself is uniform, there is no fixed-point constraint when heated. The deformation of the sealing plate body 307 is much smaller than that of the laminated board 304. When the laminated board 304 deforms and arches upwards in the middle, it is blocked and limited by the sealing plate 305, which limits the deformation of the laminated board 304 and plays a role in maintaining its flatness and reducing its deformation.

A protruding 411 is provided above a position where the fixing shaft 410 is connected to the laminated board 304, and a large-diameter hole 412 accommodates the protruding 411 is provided at a lower opening of the first through hole of the sealing plate 305.The large-diameter hole 412 contacts and connects with the protruding 411, and a bottom of the large-diameter hole 412 limits the protruding 411. A depth of the large-diameter hole 412 is equal to or greater than a height of the protruding 411, so that good contact can always be maintained between the sealing plate body 307 and the laminated board 304. By adopting the above structure, the connection depth between the fixing shaft 410 and the laminated board 304 can be ensured during installation, which is convenient to calculate a lifting distance of the laminated board 304 during lifting operations.

The lifting drive device 402 can be fixedly installed inside the upper box 3, in an implementation mode, the lifting drive device 402 is fixedly installed outside the upper box, above the upper box 3. Specifically, the output end of the lifting drive device 402 is fixedly connected to an upper end of the fixing shaft 410 through a lifting board 403. The upper end of the fixing shaft 410 passes through the second through hole 413 provided on an upper box body and is fixedly connected to a lower surface of the lifting board 403. The lifting drive device 402 is fixedly connected to the lifting board 403. An upper corrugated pipe 401 is provided between the lifting board 403 and the upper box body, and a lower corrugated pipe 405 is provided between the upper box body and the sealing plate 305. The fixing shaft 410 is located between the upper corrugated pipe 401 and lower corrugated pipe 405. The lifting board 403, the upper corrugated pipe 401, the lower corrugated pipe 405, and the laminated board 304 form a third sealing chamber. The third sealing chamber is not communicated to the second sealing chamber 2. When inflating into the second sealing chamber 2, there is no inflation in the third sealing chamber to avoid inflation pressure interference with a force exerted by the lifting drive. In an implementation mode, for the convenience of maintenance and repair, a fixing seat 406 can be fixedly installed outside the upper box body. A third through hole on the fixing seat 406 is opposite to the second through hole 413 on the upper box body. The third through hole is a non-equal diameter hole, and its lower end is a large diameter end. Inside the large diameter end, there are a first installation seat 408 and a second installation seat 409. Both first installation seat 408 and second installation seat 409 are fixedly connected to the fixing seat 406 through their side walls. Sealing members are provided between a top of the second installation seat 409 and the fixing seat 406, as well as between second installation seats 409, for sealing. A lower end of the upper corrugated pipe 401 is fixedly connected to an upper surface of the fixing seat 406, and an upper end of the lower corrugated pipe 405 is fixedly connected to a lower surface of the first installation seat 408.

The photovoltaic component laminating device 300 of the present disclosure can have two laminating methods. One is the lifting component only provides lifting power of the laminated board 304, so that the laminated board 304 approaches or leaves the photovoltaic component 202 and is not used as a pressure driving device. The power source for the laminated board 304 to apply pressure to the photovoltaic component 202 is air pressure. Specifically, it inflates the second sealing chamber 2 and pushes the sealing plate 305 downwards to apply pressure to the laminated board 304, thereby applying pressure to the photovoltaic component 202. In this laminating process, the lifting component does not apply any force to the laminated board 304, but relies on the inflation pressure to push the sealing plate 305 downwards and push the laminated board 304 downwards to transmit pressure to the photovoltaic component 202. This laminating method, due to the lack of mechanical external force, relies on the flatness of the laminated board 304 for the uniformity of pressure on the photovoltaic component 202. The better the flatness of laminated board 304, the better lamination effect. This is particularly advantageous for small-sized laminated board 304. When an area of the laminated board 304 is relatively large, the laminated board 304 itself has a certain amount of deformation. At this time, a combination of the lifting device 400 and the inflation pressure can be used for lamination. When laminating, if a thicker part of the photovoltaic component 202 is found, the lifting drive device 402 of that part can apply appropriate pressure to the laminated board 304 to compensate for the unevenness of the photovoltaic component lamination caused by the unevenness of the laminated board 304 itself. Therefore, adjustments can be made according to the actual lamination results, which are convenient and can ensure the quality of the laminated photovoltaic component 202.

In an implementation mode, a backing plate 301 is provided below the frame of the sealing plate 305 to protect the inflatable sealing ring 302. The vacuum sealing effect is adjusted by the inflatable sealing ring 302, and the backing plate 301 is fixedly connected to a lower surface of the frame in a detachable manner. The inflatable sealing ring 302 can be located inside or outside the backing plate 301. The thickness of the backing plate 301 is arranged by calculating the thickness of the photovoltaic component 202 and the deformation of the inflatable sealing ring 302, so that when the first sealing chamber 1 is sealed, the backing plate 301 can support the sealing plate 305 and prevent the sealing plate 305 from deforming downward under the inflation pressure when inflating into the second sealing chamber 2. This application uses the inflatable sealing ring 302 for sealing, which is adjusted by the inflating volume inside the inflatable sealing ring 302. They can be used for photovoltaic components 202 of different thicknesses and are limited by the backing plate 301 to protect the inflatable sealing rings 302 and provide peripheral support for the sealing plates 305.

A first sealing chamber 1 composed of the sealing plate 305 can be provided in the second sealing chamber 2, or two or more first sealing chambers 1 can be provided. One or more laminated boards 304 can be provided in one first sealing chamber 1, and each laminated board 304 has at least one lifting device 400 for driving. In this way, different structures can be adopted for different working conditions. For example, in the case of multi specification production, if there are multiple specifications of photovoltaic components 202 that need to be laminated each time and the thickness of the photovoltaic components 202 is not consistent, multiple first sealing chambers 1 can be provided in one second sealing chamber 2, with one or a small number of laminated boards 304 provided in each first sealing chamber 1. For batch production scenarios, one first sealing chamber 1 or a small number of first sealing chamber 1 can be provided in one second sealing chamber 2 to achieve batch lamination.

The lifting drive device 402 can use cylinders, electric cylinders, and other linear reciprocating drive mechanisms that can achieve distance control.

A flexible cushion layer 303 is provided on a surface opposite to the photovoltaic component 202 below each rigid laminated board 304. When the laminated board 304 contacts the photovoltaic component 202, the flexible cushion layer 303 can provide cushioning protection. The flexible cushion layer 303 is a high-temperature resistant and anti-adhesive flexible cushion layer 303 that is made of a high-temperature resistant material that can withstand temperatures above 200 °C and a Polytetrafluoroethylen, (PTFE) layer. The high-temperature resistant material can be woven fabric or industrial felt cloth, and the anti-adhesive layer can be a PTFE layer. The anti-adhesive layer is coated on the surface of the high-temperature resistant material, such as the high-temperature resistant cloth used as a photovoltaic component conveyor belt in existing technology. The flexible cushion layer 303 is provided on a lower surface of the laminated board 304. When laminated, the flexible cushion layer 303 contacts with the photovoltaic component 202, and a reverse force of the component on the laminated board 304 is first applied to the flexible cushion layer 303. The flexible cushion layer 303 deforms under the force, and then applies the force to the laminated board 304, avoiding hard contact between the component and the laminated board 304, replacing the hard deformation between the rigid laminated board 304 and the component, further avoiding or reducing the deformation of the laminated board 304 itself, and reducing the impact between the rigid laminated board 304 and the photovoltaic component 202, reducing or preventing damage to the photovoltaic component 202.

The following provides a detailed explanation of the laminating method of the present disclosure using an air cylinder as the lifting drive device 402 as an example.

When lamination is required, both the upper box 3 and the laminated board 304 are in a clearance position state, and upper box 3 and the laminated board 304 are kept away from the heating plate 201. Firstly, the photovoltaic components 202 are transported onto the heating plate 201. Once the photovoltaic components 202 are in place, the reciprocating lifting device 400 drives the upper box 3 to descend and meet the heating plate 201 to form the second sealing chamber 2; the lifting drive device 402 drives the laminated board 304 downwards, and drive the sealing plate 305 downwards to form the first sealing chamber 1 with the heating plate 201. The first sealing cavity and the second sealing can be formed simultaneously, or they can be formed first sealing cavity and then again to form the second sealing cavity. When forming the first sealing chamber 1, it is necessary to control the displacement of the lifting drive device 402. It is best to make the laminated board 304 close to the photovoltaic component without contact or contact without pressure. Vacuum the first sealing chamber 1 to reach a preset vacuum degree, inflate the second sealing chamber 2 to reach the preset pressure value, and heat and pressurize according to the process requirements. When pressurizing, the lifting drive device 402 loses control over the laminated board 304. The gas pressure drives the sealing plate 305 to move down and pressurize the photovoltaic component 202. When a preset laminating process is completed, deflate the second sealing chamber 2, inflate the first sealing chamber 1, release the vacuum in the first sealing chamber 1, and the lifting drive device 402 drives the laminated board 304 to move up and move away from the photovoltaic component 202. Then, the reciprocating driving device drives the upper box 3 to move up, and the photovoltaic component 202 is removed from the heating plate 201, and waits for a next lamination cycle. The method of causing the lifting drive device 402 to lose control over the laminated board 304 can be adjusted as needed. Taking the lifting drive device 402 using a cylinder as an example, the cylinder outputs power during initial lamination, and does not output power after the vacuum degree is reached. If a local state is not good, local adjustments can be made by inflating or reverse inflating the cylinder.

In the technical solution of the present disclosure, an inflatable laminate is formed by combining the laminated board 304, the sealing plate 305, the inflatable sealing ring 302, and the backing plate, which can replace the existing technology of rubber plate lamination and achieve lamination of solar photovoltaic components 202 without rubber plates. The laminated board 304 directly receives thermal stress, and the sealing plate 305 is in a free state, so the thermal stress is small and the deformation is small. Gas pressure is transmitted to the laminated board 304 through the sealing plate 305, and the deformation of the laminated board 304 is corrected by the sealing plate 305. The laminated board 304 is not directly subjected to gas pressure, reducing the deformation of the laminated board 304 in direct contact with the component due to thermal stress and gas pressure, thereby avoiding the occurrence of thin edges of the component.

The above is only a preferred specific embodiment of the present disclosure, but the protection scope of the present disclosure is not limited to this. Any changes or substitutions that can be easily conceived by those skilled in the art within the scope of the disclosed technology should be included in the protection scope of the present disclosure.

What is claimed is:

1. A photovoltaic component laminating device, comprising:
at least one rigid laminated board,
a lifting device, and
a rigid sealing plate,
a first accommodation chamber configured to accommodate the laminated board is provided below the sealing plate, the laminated board is provided in the first accommodation chamber,
the lifting device comprises a lifting drive device and a fixing shaft,
the sealing plate is provided above the laminated board, the lifting drive device is provided above the sealing plate, and a first through hole is provided on the sealing plate;
a lower end of the fixing shaft is fixedly connected to the laminated board, and an upper end passes through the first through hole and is fixedly connected to an output end of the lifting drive device;
the sealing plate is freely provided above the laminated board;
when the lifting drive device drives the laminated board to rise, the sealing plate is driven to rise by the laminated board;
when the lifting drive device drives the laminated board to descend, the sealing plate descends synchronously with the laminated board by its own weight,
when there are two or more laminated boards, and the two or more the laminated boards are horizontally arranged in parallel, and each of laminated boards is provided with at least one lifting device.

2. The photovoltaic component laminating device according to claim 1, wherein the sealing plate is hung on a protruding of the fixing shaft through an opening of the through hole, so that the sealing plate is configured to contact and connect with the laminated board and maintain a free state, and a lower surface of the laminated board faces the heating device.

3. The photovoltaic component laminating device according to claim 1, wherein a sealing device is provided on a lower end surface of the sealing plate, and the sealing device is an inflatable sealing ring;
the inflatable sealing ring is communicated to an inflation device and an exhaust device respectively,
a height of the first accommodation chamber is adjusted by adjusting an inflation amount of the inflatable sealing ring;
a backing plate is provided on a lower end surface of the sealing plate on an inner side or an outer side of the sealing device, and the backing plate is configured to support the sealing plate;
a flexible cushion layer is fixedly provided on a surface of laminated boards that is opposite the photovoltaic component.

4. The photovoltaic component laminating device according to claim 1, wherein the lifting drive device is a linear reciprocating driving device configured to control a lifting displacement of the laminated board, and the linear reciprocating driving device is a cylinder, an electric cylinder, or a servo motor.

5. A photovoltaic component laminating machine, comprising: an upper box and a heating plate, wherein the photovoltaic component laminating device according to claim 1 is used, wherein a second accommodation chamber configured to accommodate the sealing plate and the laminated plate is provided below an upper box body,
the sealing plate is provided in the second accommodation chamber, the upper box is provided above the heating plate, and the two are configured to approach and move away from each other;
when they approach each other, they form a second sealing chamber, and when they move away from each other, a lid is opened and space is left, at least one sealing plate is provided in the second accommodation chamber;
when the lifting device drives the laminated board to move down to its position, a first sealing chamber is formed between the sealing plate and the heating plate;
after the lifting device moves up, the sealing plate and the laminated board move away from the heating plate, and the first sealing chamber is communicated to an inflation device and a vacuum extraction device respectively, the second sealing chamber is communicated to the inflation device and the vacuum extraction device respectively.

6. The photovoltaic component laminating machine according to claim 5, wherein when laminating, the upper box body and sealing plate are first combined with the heating plate to form the first sealing chamber and the second sealing chamber, respectively, and then pressure is applied to the photovoltaic component;
applying pressure to the photovoltaic component, inflating the second sealing chamber as an applied pressure and the lifting drive device does not apply pressure, or inflating the second sealing chamber as a main applied pressure and the lifting drive device applies an auxiliary pressure;
wherein the auxiliary pressure of the lifting drive device is applied in an area where the pressure needs to be increased.

7. The photovoltaic component laminating machine according to claim 6, wherein when the sealing plate and the laminated board are descended into place, the laminated board does not apply pressure to the photovoltaic component, and when the second sealing chamber is inflated, the laminated board begins to apply pressure to the photovoltaic component.

8. The photovoltaic component laminating machine according to claim 5, wherein the lifting drive device is provided outside the upper box body, and a second through hole is provided on the upper box body;
an upper end of the fixing shaft passes through the second through hole, and the lifting drive device is fixedly connected to the upper end of the fixing shaft through a lifting board;
a corrugated pipe is provided between the lifting board and the upper box body, and an upper end of the corrugated pipe is connected to the lifting board in a sealing manner, and a lower end is connected to the upper box body in a sealing manner;
the fixing shaft is provided inside the corrugated pipe and passes through the second through hole in a sealing manner through the corrugated pipe.

9. The photovoltaic component laminating machine according to claim 8, wherein there are two corrugated pipes, namely an upper corrugated pipe and a lower corrugated pipe; an upper end of the upper corrugated pipe is fixedly connected to the lifting board in a sealing manner, and a lower end thereof is fixedly connected to the upper box body in a sealing manner;
an upper end of the lower corrugated pipe is fixedly connected to the upper box body in a sealing manner, and a lower end thereof is fixedly connected to the sealing plate in a sealing manner;
the fixing shaft is provided in the upper corrugated pipe and the lower corrugated pipe.

10. The photovoltaic component laminating machine according to claim 9, wherein a fixing seat is fixedly provided on the upper box body, and a third through hole is provided on the fixing seat, the third through hole is arranged opposite to the second through hole;
a first installation seat and a second installation seat are provided in a large-diameter hole of the third through hole; side walls of the first installation seat and the second installation seat are fixedly connected to a through hole wall of the fixing seat, and both the first installation seat and second installation seat are provided with through holes for the fixing shaft to pass through;
an upper surface of the first installation seat is fixedly connected to a lower surface of the fixing seat in a sealing manner, and a lower surface of the first installation seat is fixedly connected to the upper surface of the second installation seat in a sealing manner;
an upper end of the lower corrugated pipe is fixedly connected to the second installation seat in a sealing manner and is provided with an adapter shaft, the adapter shaft is in a shape of “T”, a top of the adapter shaft that is in “—” character shape is fixedly connected to the lifting board, and a lower end thereof is fixedly connected to the fixing shaft;
a connection position between the fixing shaft and the adapter shaft is provided in the through hole of the fixing seat;
the fixing shaft and the adapter shaft are fixedly connected and coaxially arranged.
